(19) United States
(12) Patent Application Publication
(10) Pub. No.: US 2023/0155080 A1
(43) Pub. Date: May 18, 2023

(54) DISPLAY DEVICE, LIGHT-EMITTING DEVICE AND ELECTRONIC APPARATUS

(71) Applicant: Sony Group Corporation, Tokyo (JP)

(72) Inventors: Hiroshi Fujimaki, Kanagawa (JP); Hiroshi Nishikawa, Kanagawa (JP)

(21) Appl. No.: 18/007,587

(22) PCT Filed: Jul. 2, 2021
(86) PCT No.: PCT/JP2021/025174

§ 371 Date: Dec. 1, 2022

(30) Foreign Application Priority Data
Jul. 10, 2020 (JP) 2020-119305

(51) Int. Cl. H01L 33/54; H01L 33/38; H01L 27/15

(52) U.S. Cl. CPC H01L 33/54; H01L 33/382; H01L 27/156

(57) ABSTRACT

Provided is a display device capable of suppressing deterioration in reliability. A display device includes: a plurality of light-emitting elements; a contact portion provided around a region in which the plurality of light-emitting elements are formed; an insulating layer having a step on the contact portion; and a protective layer covering the light-emitting elements, the contact portion, and the insulating layer. The light-emitting element includes: a first electrode; a second electrode having a peripheral portion connected to the contact portion; and a light-emitting layer provided between the first electrode and the second electrode. The step rises in a direction from an inner side of the display device toward an outer circumference side, and A peripheral edge of the second electrode is provided closer to the region than the step.

### TECHNICAL FIELD

The present disclosure relates to display devices, light-emitting devices, and electronic apparatuses.

### BACKGROUND ART

As a light-emitting device such as a display device or a lighting device, there is known a light-emitting device including a light-emitting element having a light-emitting layer provided between a pair of electrodes and a protective layer covering the light-emitting element. The light-emitting device having the above-mentioned configuration has a step in a peripheral region that rises in a direction from the inner side of the light-emitting device toward the outer circumference side, and one electrode that constitutes the light-emitting element extends beyond the step to the outer circumference side of the light-emitting device. For example, PTL 1 discloses an organic light-emitting device 1 in which a pixel separation film 12 has a step on a wiring connection portion (contact portion) 24 that rises in the direction from the inner side of the organic light-emitting device 1 toward the outer circumference, and an upper electrode 23 extends beyond the step to the outer circumference of the organic light-emitting device 1.

### CITATION LIST

### Patent Literature

[PTL 1]
JP 2016-21380 A

### SUMMARY

### Technical Problem

However, as described above, in the light-emitting device in which one of the electrodes constituting the light-emitting element extends beyond the step to the outer circumference side, cracks may occur on the side surface (end surface) of a protective layer covering the contact portion. When such cracks occur, moisture or the like enters the display device from the side surfaces of the protective layer through the cracks, which lowers the reliability of the light-emitting device.

An object of the present disclosure is to provide a display device, a light-emitting device, and an electronic apparatus capable of suppressing deterioration in reliability.

### Solution to Problem

In order to solve the above-mentioned problems, a first disclosure provides:

a display device including: a plurality of light-emitting elements;
a contact portion provided around a region in which the plurality of light-emitting elements are formed;
an insulating layer having a step on the contact portion; and
a protective layer covering the light-emitting elements, the contact portion, and the insulating layer, wherein
each of the light-emitting elements includes:
a first electrode;
a second electrode having a peripheral portion connected to the contact portion; and
a light-emitting layer disposed between the first electrode and the second electrode, wherein
the step rises in a direction from an inner side of the display device toward an outer circumference side, and
a peripheral edge of the second electrode is provided closer to the region than the step.

A second disclosure provides:

a light-emitting device including: a plurality of light-emitting elements;
a contact portion provided around a region in which the plurality of light-emitting elements are formed;
an insulating layer having a step on the contact portion; and
a protective layer covering the light-emitting elements, the contact portion, and the insulating layer, wherein
each of the light-emitting elements includes:
a first electrode;
a second electrode having a peripheral portion connected to the contact portion; and
a light-emitting layer disposed between the first electrode and the second electrode, wherein
the step rises in a direction from an inner side of the light-emitting device toward an outer circumference side, and
a peripheral edge of the second electrode is provided closer to the region than the step.

A third disclosure provides:

a display device including: a plurality of light-emitting elements;
an insulating layer having a step around a region in which the plurality of light-emitting elements are formed; and
a protective layer covering the light-emitting elements and the insulating layer, wherein
each of the light-emitting elements includes:
a first electrode;
a second electrode having a peripheral edge extending to a periphery of the region; and
a light-emitting layer disposed between the first electrode and the second electrode, wherein
the step rises in a direction from an inner side of the display device toward an outer circumference side, and
a peripheral edge of the second electrode is provided closer to the region than the step.

A fourth disclosure provides:

a light-emitting device including: a plurality of light-emitting elements;
an insulating layer having a step around a region in which the plurality of light-emitting elements are formed; and
a protective layer covering the light-emitting elements and the insulating layer, wherein
each of the light-emitting elements includes:
a first electrode;
a second electrode having a peripheral edge extending to a periphery of the region; and
a light-emitting layer disposed between the first electrode and the second electrode, wherein
the step rises in a direction from an inner side of the light-emitting device toward an outer circumference side, and
a peripheral edge of the second electrode is provided closer to the region than the step.

A fifth disclosure provides an electronic apparatus including the display device according to any one of the first disclosure and second disclosure, or the light-emitting device according to any one of third disclosure and fourth disclosure.

### BRIEF DESCRIPTION OF DRAWINGS

FIG. 1 is a plan view showing a configuration example of a display device according to an embodiment of the present disclosure.

FIG. 2 is a cross-sectional view taken along line II-II of FIG. 1.

FIG. 3 is an enlarged plan view showing a portion of the display device.

FIG. 4 is a cross-sectional view showing the configuration of a conventional display device.

FIG. 5 is a cross-sectional view showing a configuration example of a display device according to Modification Example 1.

FIG. 6 is a cross-sectional view showing a first configuration example of a display device according to Modification Example 2.

FIG. 7 is a cross-sectional view showing a second configuration example of the display device according to Modification Example 2.

FIG. 8 is a plan view showing a configuration example of a display device according to Modification Example 3.

FIG. 9 is a cross-sectional view showing a first configuration example of a step.

FIG. 10 is a cross-sectional view showing a second configuration example of a step.

FIG. 11 is a cross-sectional view showing a configuration example of a display device according to Modification Example 4.

FIG. 12A is a front view showing an example of the appearance of a digital still camera. FIG. 12B is a rear view showing an example of the appearance of the digital still camera.

FIG. 13 is a perspective view of an example of the appearance of a head-mounted display.

FIG. 14 is a perspective view showing an example of the appearance of a television device.

FIG. 15 is a perspective view showing an example of the appearance of a lighting device.

### DESCRIPTION OF EMBODIMENTS

An embodiment of the present disclosure will be described in the following order.

In addition, in all drawings of the following embodiments, the same or corresponding parts are denoted by the same reference numerals.

1 Configuration of display device
2 Manufacturing method of display device
3 Operation and effect

### 4 Modification Example

### 5 Application Example

### 1 CONFIGURATION OF DISPLAY DEVICE

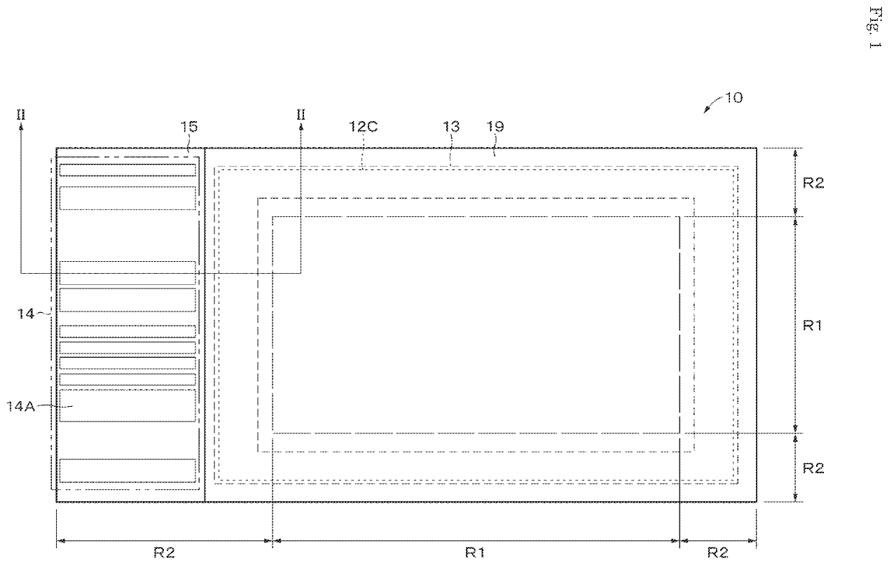

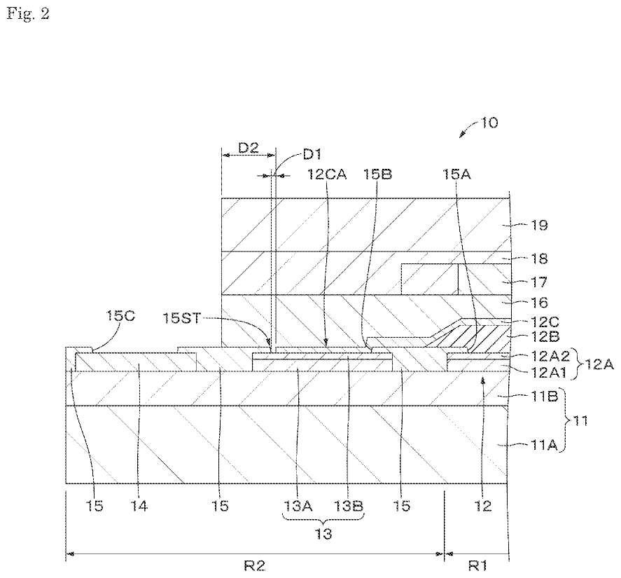

FIG. 1 is a plan view showing a configuration example of an organic EL (Electroluminescence) display device 10 (hereinafter simply referred to as “display device 10”) according to an embodiment of the present disclosure. FIG. 2 is a cross-sectional view taken along line II-II of FIG. 1. The display device 10 includes a drive substrate 11, a plurality of light-emitting elements 12, a contact portion 13, a pad portion 14, an insulating layer 15, a protective layer 16, a color filter 17, a filling resin layer 18, and a counter substrate 19.

The display device 10 is an example of a light-emitting device. The display device 10 is a top-emission-type display device. The drive substrate 11 constitutes the display surface side of the display device 10, and the counter substrate 19 constitutes the rear surface side of the display device 10. The counter substrate 19 side is the top side, and the substrate 11A side is the bottom side. In the following description, in each layer constituting the display device 10, the surface on the display surface side of the display device 10 is referred to as a first surface, and the surface on the rear surface side of the display device 10 is referred to as a second surface.

The display device 10 has an element formation region R1 and a peripheral region R2. The element formation region R1 is a region in which a plurality of light-emitting elements 12 are formed. The peripheral region R2 is a region provided around the element formation region R1. The peripheral region R2 has a closed loop shape surrounding the element formation region R1.

The display device 10 may be a microdisplay. The display device 10 may be used in various electronic apparatuses. Electronic apparatuses using the display device 10 include, for example, display devices for VR (Virtual Reality), MR (Mixed Reality), and AR (Augmented Reality), and an electronic view finder (EVF), a small projector, and the like.

(Substrate)

The drive substrate 11 is a so-called backplane and drives the plurality of light-emitting elements 12. The drive substrate 11 includes a substrate 11A and an insulating layer 11B.

On the first surface of the substrate 11A, there are provided a drive circuit including sampling transistors and driving transistors for controlling driving of the plurality of light-emitting elements 12, a power supply circuit for supplying power to the plurality of light-emitting elements 12, an underlying wiring, and the like (neither of which are shown). The drive circuit and the power supply circuit are disposed, for example, in the element formation region R1. The underlying wiring is disposed, for example, in the peripheral region R2.

The substrate 11A may be made of, for example, glass or resin having low moisture and oxygen permeability, or may be made of a semiconductor that facilitates the formation of transistors and the like. Specifically, the substrate 11A may be a glass substrate, a semiconductor substrate, a resin substrate, or the like. Glass substrates include, for example, high strain-point glass, soda glass, borosilicate glass, forsterite, lead glass, or quartz glass. Semiconductor substrates include, for example, amorphous silicon, polycrystalline silicon, monocrystalline silicon, or the like. The resin substrates include, for example, at least one selected from the group consisting of polymethyl methacrylate, polyvinyl alcohol, polyvinyl phenol, polyethersulfone, polyimide, polycarbonate, polyethylene terephthalate and polyethylene naphthalate.

The insulating layer 11B is provided on the first surface of the substrate 11A and covers the drive circuit, the power supply circuit, the underlying wiring, and the like. The insulating layer 11B has a plurality of first contact plugs (not shown). The first contact plug connects the first electrode 12A forming the light-emitting element 12 and the drive circuit. The insulating layer 11B further includes one or more second contact plugs (not shown). The second contact plug connects the contact portion 13 and the underlying wiring.

The insulating layer 11B is made of, for example, an organic material or an inorganic material. The organic material includes, for example, at least one of polyimide and acrylic resin. The inorganic material includes, for example, at least one of silicon oxide, silicon nitride, silicon oxynitride, and aluminum oxide.

(Light-Emitting Element)

A plurality of light-emitting elements 12 are provided in the element formation region R1 on the first surface of the drive substrate 11. The plurality of light-emitting elements 12 are, for example, two-dimensionally arranged in a prescribed arrangement pattern such as a matrix in the element formation region R1. The light-emitting element 12 is configured to emit white light. The light-emitting element 12 is, for example, a white OLED or a white micro-OLED (MOLED). In the present embodiment, a method using the light-emitting element 12 and the color filter 17 is used as a method for colorization in the display device 10. However, the colorization method is not limited to this, and an RGB coloring method or the like may be used. Also, instead of the color filter 17, a monochromatic filter may be used.

The light-emitting element 12 includes a first electrode 12A, an organic layer 12B, and a second electrode 12C. The first electrode 12A, the organic layer 12B, and the second electrode 12C are laminated in this order from the drive substrate 11 side toward the counter substrate 19.

(First Electrode)

The first electrode 12A is provided on the first surface of the drive substrate 11. The first electrode 12A is electrically separated for each sub-pixel. The first electrode 12A is the anode. The first electrode 12A also functions as a reflective layer, and is preferably made of a material having a reflectance as high as possible and a work function as large as possible in order to increase the luminous efficiency.

The first electrode 12A is configured of at least one layer of a metal layer 12A1 and a metal oxide layer 12A2. More specifically, the first electrode 12A is configured of a single layer film of the metal layer 12A1 or the metal oxide layer 12A2, or a laminated film of the metal layer 12A1 and the metal oxide layer 12A2. Note that FIG. 2 shows an example in which the first electrode 12A is configured of a laminated film. When the first electrode 12A is configured of a laminated film, the metal oxide layer 12A2 may be provided on the organic layer 12B side, and the metal layer 12A1 may be provided on the organic layer 12B side. From the viewpoint of placing a layer having a high work function adjacent to the organic layer 12B, it is preferable that the metal oxide layer 12A2 is provided on the organic layer 12B side.

The metal layer 12A1 is made of, for example, at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer 12A1 may contain the at least one metal element as a constituent element of an alloy. Specific examples of alloys include aluminum alloys and silver alloys. Specific examples of aluminum alloys include AlNd and AlCu.

The metal oxide layer 12A2 includes, for example, at least one of a mixture of indium oxide and tin oxide (ITO), a mixture of indium oxide and zinc oxide (IZO), and titanium oxide (TiO).

(Second Electrode)

The second electrode 12C is provided so as to face the first electrode 12A. The second electrode 12C is provided as a common electrode for all sub-pixels within the element formation region R1. The second electrode 12C is the cathode. The second electrode 12C is a transparent electrode that is transparent to the light generated in the organic layer 12B. Here, the transparent electrode includes a semi-transmissive reflective layer. The second electrode 12C is preferably made of a material having a transmittance as high as possible and a work function as small as possible in order to increase the luminous efficiency.

The second electrode 12C is configured of at least one layer of a metal layer and a metal oxide layer. More specifically, the second electrode 12C is configured of a single layer film of a metal layer or a metal oxide layer, or a laminated film of a metal layer and a metal oxide layer. When the second electrode 12C is configured of a laminated film, the metal layer may be provided on the organic layer 12B side, and the metal oxide layer may be provided on the organic layer 12B side. From the viewpoint of placing a layer having a low work function adjacent to the organic layer 12B, it is preferable that the second electrode 12C is provided on the organic layer 12B side.

The metal layer contains, for example, at least one metal element selected from the group consisting of magnesium (Mg), aluminum (Al), silver (Ag), calcium (Ca) and sodium (Na). The metal layer may contain the at least one metal element as a constituent element of an alloy. Specific examples of alloys include MgAg alloys, MgAl alloys, AILi alloys, and the like. Metal oxides include, for example, at least one of a mixture of indium oxide and tin oxide (ITO), a mixture of indium oxide and zinc oxide (IZO), and zinc oxide (ZnO).

(Organic Layer)

The organic layer 12B is provided between the first electrode 12A and the second electrode 12C. The organic layer 12B is provided as an organic layer common for all sub-pixels within the element formation region R1. The organic layer 12B is configured to emit white light.

The organic layer 12B has a configuration in which a hole injection layer, a hole transport layer, a light-emitting layer, and an electron transport layer are laminated in this order from the first electrode 12A toward the second electrode 12C. Note that the configuration of the organic layer 12B is not limited to this, and layers other than the light-emitting layer are provided as necessary.

The hole injection layer is a buffer layer for increasing the efficiency of hole injection into the light-emitting layer and suppressing leakage. The hole transport layer is for increasing the efficiency of transporting holes to the light-emitting layer. In the light-emitting layer, recombination of electrons and holes occurs when an electric field is applied to generate light. The light-emitting layer is an organic light-emitting layer containing an organic light-emitting material. The electron transport layer is for enhancing the efficiency of transporting electrons to the light-emitting layer. An electron injection layer may be provided between the electron transport layer and the second electrode 12C. This electron injection layer is for enhancing the electron injection efficiency.

(Contact Portion)

The contact portion 13 is an auxiliary electrode that connects the second electrode 12C and an underlying wiring (not shown). A first surface of the contact portion 13 is connected to a peripheral portion 12CA of the second electrode 12C. On the other hand, the second surface of the contact portion 13 is connected to the underlying wiring through a contact plug. In this specification, the peripheral portion 12CA of the second electrode 12C refers to a region having a predetermined width toward the inner side from the peripheral edge of the second electrode 12C.

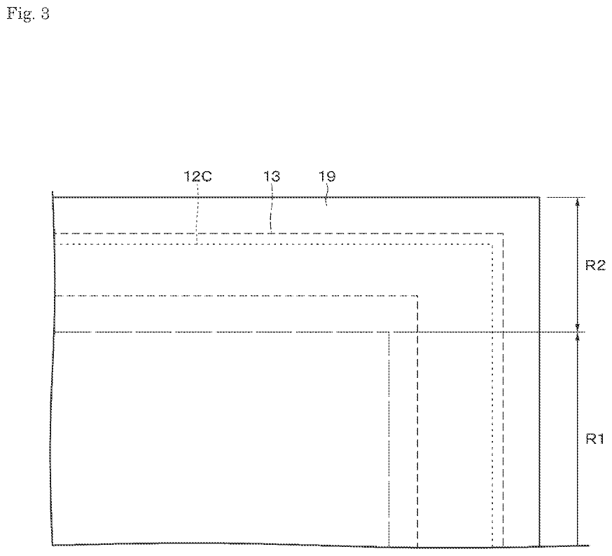

FIG. 3 is an enlarged plan view showing a portion of the display device 10. The contact portion 13 is provided in the peripheral region R2 on the first surface of the drive substrate 11. As shown in FIG. 3, the contact portion 13 has a rectangular closed loop shape surrounding the rectangular element formation region R1. That is, the contact portion 13 has a corner portion.

The contact portion 13 is configured of at least one of the metal layer 13A and the metal oxide layer 13B. More specifically, the contact portion 13 is configured of a single layer film of the metal layer 13A or the metal oxide layer 13B, or a laminated film of the metal layer 13A and the metal oxide layer 13B. Note that FIG. 2 shows an example in which the contact portion 13 is formed of a laminated film. When the contact portion 13 is configured of a laminated film, the metal oxide layer 13B may be provided on the second electrode 12C side, and the metal layer 13A may be provided on the second electrode 12C side.

As a constituent material of the contact portion 13, the same material as that of the above-described first electrode 12A can be exemplified. Specifically, as the constituent materials of the metal layer 13A and the metal oxide layer 13B of the contact portion 13, the same materials as those of the metal layer 12A1 and the metal oxide layer 12A2 of the first electrode 12A can be exemplified.

The contact portion 13 may have the same configuration as the first electrode 12A. The metal layer 13A and the metal oxide layer 13B of the contact portion 13 may have the same configurations as the metal layer 12A1 and the metal oxide layer 12A2 of the first electrode 12A, respectively.

(Insulating Layer)

The insulating layer 15 is provided in the element formation region R1 and the peripheral region R2 on the first surface of the drive substrate 11. The insulating layer 15 electrically separates the respective first electrodes 12A for each light-emitting element 12 (that is, for each sub-pixel) in the element formation region R1. The insulating layer 15 has a plurality of first openings 15A, and the first surfaces of the separated first electrodes 12A (surfaces facing the second electrodes 12C) are exposed through the first openings 15A. The insulating layer 15 may cover the peripheral portion of the first surface of the separated first electrode 12A to the side surface (end surface). In this specification, the peripheral portion of the first surface refers to a region having a predetermined width toward the inner side from the peripheral edge of the first surface.

The insulating layer 15 electrically separates the respective light-emitting elements 12 located in the peripheral portion of the element formation region R1 from the contact portion 13 provided in the peripheral region R2. The insulating layer 15 has a second opening 15B, and the first surface of the contact portion 13 is exposed through the second opening 15B. The second opening 15B has, for example, a closed loop shape. The insulating layer 15 may cover the peripheral portion of the first surface of the contact portion 13 to the side surface (end surface) of the contact portion 13.

The insulating layer 15 electrically separates the contact portion 13 and the pad portion 14 provided in the peripheral region R2. The insulating layer 15 has a third opening 15C, and the contact portion 13 is exposed through the third opening 15C.

The insulating layer 15 has a step 15ST in the peripheral region R2. Specifically, the insulating layer 15 has a step 15ST on the first surface of the contact portion 13. The step 15ST extends in the circumferential direction of the peripheral region R2. The step 15ST rises in the direction from the inner side of the display device 10 to the outer circumference side. The peripheral edge of the second electrode 12C is provided in the vicinity of the step 15ST on the side closer to the element formation region R1 than the step 15ST. Accordingly, it is possible to suppress the occurrence of a step in the peripheral region R2 due to the side surface (end surface) of the second electrode 12C. Therefore, it is possible to suppress the occurrence of cracks in the protective layer 16 in the peripheral region R2. In the present disclosure, the crack may be a crack that occurs when the protective layer 16 is formed by chemical vapor deposition, physical vapor deposition, or the like (for example, CVD), or may be a crack that occurs due to stress acting on the protective layer 16 after the protective layer 16 is formed.

From the viewpoint of suppressing the occurrence of cracks, the distance D1 between the step 15ST and the peripheral edge of the second electrode 12C in the in-plane direction of the display surface is preferably 10 μm or less, more preferably 5 μm or less, even more preferably 2 μm or less, and particularly preferably 1 μm or less.

From the viewpoint of suppressing the occurrence of cracks, the height of the step 15ST is preferably substantially equal to the height of the side surface of the second electrode 12C. In the present embodiment, the side surface of the second electrode 12C is located on the contact portion 13.

In the present embodiment, the step 15ST is a step between the first surface of the contact portion 13 and the first surface of the insulating layer 15. That is, the step 15ST is formed by the inner wall of the second opening 15B. As a constituent material of the insulating layer 15, the same material as that of the insulating layer 11B described above can be exemplified.

(Protective Layer)

The protective layer 16 is provided on the first surface of the second electrode 12C and covers the light-emitting element 12, the peripheral portion 12CA of the second electrode 12C, the contact portion 13, the insulating layer 15, and the like. The protective layer 16 shields the light-emitting element 12, the peripheral portion 12CA of the second electrode 12C, the contact portion 13, and the like from the outside air, and suppresses moisture from entering the light-emitting element 12, the peripheral portion 12CA of the second electrode 12C, the contact portion 13, and the like from the external environment. Moreover, when the second electrode 12C is configured of a metal layer, the protective layer 16 may have a function of suppressing oxidation of this metal layer.

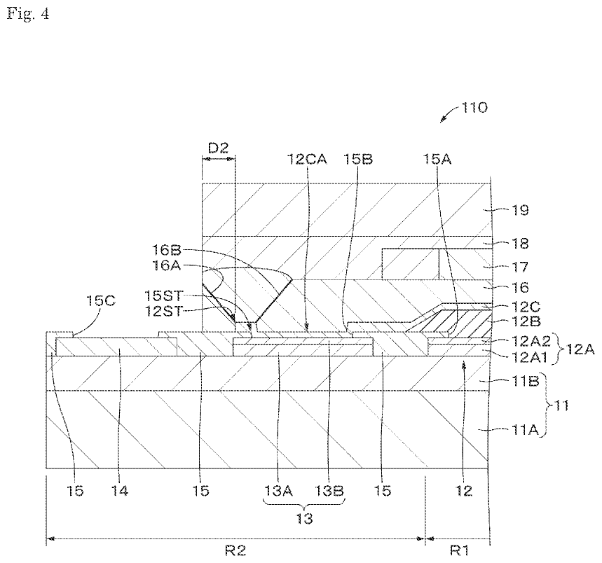

From the viewpoint of narrowing the frame of the display device 10, the distance D2 between the peripheral edge of the protective layer 16 and the peripheral edge of the second electrode 12C in the in-plane direction of the display surface is preferably 10 μm or less, more preferably 5 μm or less, even more preferably 2 μm or less, and particularly preferably 1 μm or less. In the display device 10 according to an embodiment, even when the frame is narrowed so that the distance D2 is 10 μm or less, it is possible to suppress one end of a crack occurred in the peripheral region R2 of the display device 10 from reaching the side surface (end surface) of the protective layer 16. In the display device 110 having the conventional configuration, if the frame is narrowed so that the distance D2 is 10 μm or less, one end of the crack 16A easily reaches the side surface (end surface) of the protective layer 16 (see FIG. 4).

The protective layer 16 is made of, for example, an inorganic material. As the inorganic material constituting the protective layer 16, one having low hygroscopicity is preferable. Specifically, the inorganic material constituting the protective layer 16 preferably includes at least one selected from the group consisting of silicon oxide (SiO), silicon nitride (SiN), silicon oxynitride (SiNO), titanium oxide (TiO) and aluminum oxide (AlO). The protective layer 16 may have a single-layer structure, but may have a multi-layer structure when the thickness is increased. This is for alleviating the internal stress in the protective layer 16.

(Color Filter)

The color filter 17 is provided on the protective layer 16. The color filter 17 is, for example, an on-chip color filter (OCCF). The color filter 17 includes, for example, a red filter, a green filter and a blue filter. A red filter, a green filter, and a blue filter are provided so as to face the light-emitting element 12 for the red sub-pixel, the light-emitting element 12 for the green sub-pixel, and the light-emitting element 12 for the blue sub-pixel, respectively. As a result, white light emitted from each light-emitting element 12 in the red sub-pixel, green sub-pixel, and blue sub-pixel passes through the red filter, green filter, and blue filter, respectively, whereby red light, green light, and blue light are emitted from the display surface. A light-shielding layer (not shown) may be provided between the color filters of each color, that is, between the sub-pixels. Note that the color filters 17 are not limited to on-chip color filters, and may be provided on one main surface of the counter substrate 19.

(Filling Resin Layer)

The filling resin layer 18 is provided between the color filter 17 and the counter substrate 19. The filling resin layer 18 functions as an adhesive layer that bonds the color filter 17 and the counter substrate 19 together. The filling resin layer 18 contains, for example, at least one of a thermosetting resin and an ultraviolet curable resin.

(Counter Substrate)

The counter substrate 19 is provided so as to face the drive substrate 11. More specifically, the counter substrate 19 is provided such that the second surface of the counter substrate 19 and the first surface of the drive substrate 11 face each other. The counter substrate 19 and the filling resin layer 18 seal the light-emitting element 12, the color filter 17, the contact portion 13, and the like. The counter substrate 19 is made of a material such as glass that is transparent to each color of light emitted from the color filters 17.

(Pad Portion)

The pad portion 14 is a connection portion for electrically connecting the display device 10 to an electronic apparatus or the like. The pad portion 14 is provided with a plurality of connection terminals 14A. The pad portion 14 is connected to a main board or the like of the electronic apparatus via a connection member such as a flexible printed wiring board.

### 2 MANUFACTURING METHOD OF DISPLAY DEVICE

An example of a method for manufacturing the display device 10 according to an embodiment of the present disclosure will be described below. In this manufacturing method, a case where the first electrode 12A and the contact portion 13 have the same configuration (that is, the laminated film of the metal layer 12A1 and the metal oxide layer 12A2) will be described. However, the first electrode 12A and the contact portion 13 may have different configurations.

First, a drive circuit, a power supply circuit, an underlying wiring, and the like are formed on the first surface of the substrate 11A using, for example, thin film formation technology, photolithography technology, and etching technology. Next, the insulating layer 11B is formed on the first surface of the substrate 11A so as to cover the drive circuit, the power supply circuit, the underlying wiring, and the like by, for example, the CVD method. After that, a plurality of first contact plugs, one or a plurality of second contact plugs, and the like are formed on the insulating layer 11B. In this way, the drive substrate 11 is formed.

Next, after forming a laminated film of the metal layer 12A1 and the metal oxide layer 12A2 on the first surface of the drive substrate 11 by, for example, sputtering, the laminated film is patterned by, for example, photolithography technology and etching technology. Thus, the first electrodes 12A and the contact portions 13 separated for each light-emitting element 12 (that is, for each sub-pixel) are formed.

Next, the insulating layer 15 is formed on the first surface of the drive substrate 11 so as to cover the plurality of first electrodes 12A and the contact portions 13 by, for example, the CVD method, and then the insulating layer 15 is patterned using a photolithography technology and an etching technology. In this way, a plurality of first openings 15A, second openings 15B, and third openings 15C are formed in the insulating layer 15.

Next, a hole injection layer, a hole transport layer, a light-emitting layer, and an electron transport layer are laminated in this order on the first surface of the first electrode 12A and the first surface of the insulating layer 15 by a vapor deposition method, for example. By doing so, the organic layer 12B is formed. Next, the second electrode 12C is formed on the first surfaces of the organic layer 12B and the contact portion 13 by, for example, a vapor deposition method or a sputtering method. As a result, a plurality of light-emitting elements 12 are formed on the first surface of the drive substrate 11, and the peripheral portion 12CA of the second electrode 12C is joined to the contact portion 13.

Next, after forming the protective layer 16 on the first surface of the second electrode 12C by, for example, a CVD method or a vapor deposition method, the color filter 17 is formed on the first surface of the protective layer 16 by, for example, photolithography. A planarization layer may be formed above, below, or both above and below the color filter 17 in order to planarize the step of the protective layer 16 and the step due to the film thickness difference of the color filter 17 itself. Next, after the color filters 17 are covered with the filling resin layer 18 using, for example, the ODF (One Drop Fill) method, the counter substrate 19 is placed on the filling resin layer 18. Next, for example, by applying heat to the filling resin layer 18 or irradiating the filling resin layer 18 with ultraviolet rays to harden the filling resin layer 18, the drive substrate 11 and the counter substrate 19 are bonded together via the filling resin layer 18. In this way, the display device 10 is sealed. As described above, the display device 10 shown in FIGS. 1 and 2 is obtained.

### 3 OPERATION AND EFFECT

FIG. 4 is a cross-sectional view showing the configuration of a display device 110 according to a conventional example. In the display device 110 according to the conventional example, the peripheral edge of the second electrode 12C is provided over the step 15ST. Therefore, a step 12ST is formed in the vicinity of the side surface (end surface) of the protective layer 16 by the side surface (end surface) of the second electrode 12C. Therefore, when the protective layer 16 is formed by chemical vapor deposition or physical vapor deposition (for example, CVD), a crack 16A may occur from the steps 12ST toward the side surfaces of the protective layer 16. Moreover, there is a possibility that the crack 16A may occur due to the stress acting on the protective layer 16 after the protective layer 16 is formed. Therefore, the reliability of the display device 110 deteriorates.

When the frame of the display device 110 according to the conventional example is narrowed (for example, D2<10 μm), the distance from the step 12ST to the side surface of the protective layer 16 becomes short. Thus, the crack 16A becomes particularly easy to reach the side surface of the protective layer 16 from the step 12ST. Therefore, when the frame of the display device 110 according to the conventional example is narrowed, the reliability is particularly likely to deteriorate.

Incidentally, as shown in FIG. 4, a crack 16B may occur from the vicinity of the step 15ST toward the first surface of the protective layer 16. However, since the crack 16B is not electrically connected to the outside of the display device 10, the influence of the crack 16B on the reliability of the display device 110 is much less than the influence of the crack 16A on the reliability of the display device 110.

In contrast, as described above, in the display device 10 according to an embodiment, the peripheral edge of the second electrode 12C is provided in the vicinity of the step 15ST on the side closer to the element formation region R1 than the step 15ST. In this way, it is possible to suppress the formation of the step 12ST (see FIG. 4) in the vicinity of the peripheral edge (side surface) of the protective layer 16. Therefore, when the protective layer 16 is formed by chemical vapor deposition, physical vapor deposition, or the like (for example, CVD), it is possible to suppress a crack 16A (see FIG. 4) from occurring from the side surface of the second electrode 12C toward the side surface of the protective layer 16. Also, it is possible to suppress the crack 16A from occurring due to the stress acting on the protective layer 16 after the protective layer 16 is formed. Therefore, deterioration in reliability of the display device 10 can be suppressed. Such an effect of suppressing reliability deterioration becomes remarkable in the display device 10 having a narrow frame (for example, D2<10 μm).

### 4 MODIFICATION EXAMPLE

### Modification Example 1

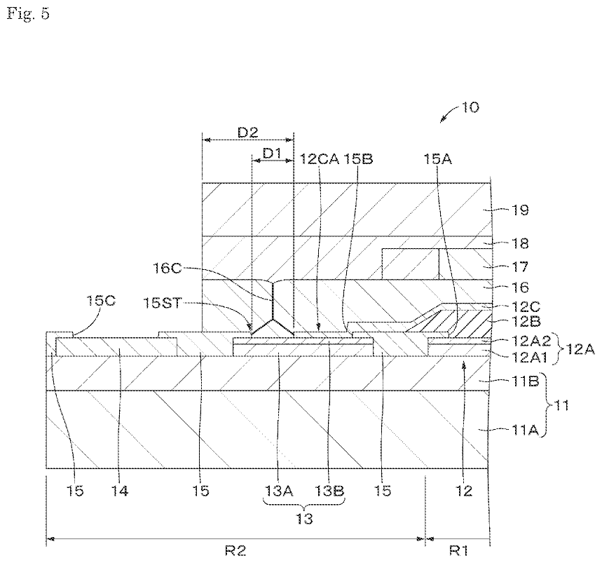

In the above-described embodiment, an example in which the peripheral edge of the second electrode 12C is provided in the vicinity of the step 15ST on the side closer to the element formation region R1 than the step 15ST has been described. However, as shown in FIG. 5, the peripheral edge of the second electrode 12C may be provided away from the step 15ST on the side closer to the element formation region R1 than the step 15ST. Specifically, for example, the distance D1 between the step 15ST and the peripheral edge of the second electrode 12C in the in-plane direction of the display surface may exceed 10 μm. In this case, a recess may be formed on the first surface of the contact portion 13 by the step 15ST and the side surface of the second electrode 12C.

In the display device 10 according to Modification Example 1, cracks 16C generated from the step 15ST and the side surfaces (end surfaces) of the second electrode 12C during or after the formation of the protective layer 16 meet at a position between the step 15ST and the second electrode 12C and extend from the second surface of the protective layer 16 toward the first surface. Therefore, it is possible to suppress the occurrence of cracks 16A (see FIG. 4) extending from the inside of the protective layer 16 toward the side surface of the protective layer 16. Therefore, deterioration in reliability of the display device 10 can be suppressed. As described above, the influence of the crack 16C that is not electrically connected to the outside on the reliability of the display device 10 is much smaller than the influence of the crack 16A that is electrically connected to the outside on the reliability of the display device 110.

### Modification Example 2

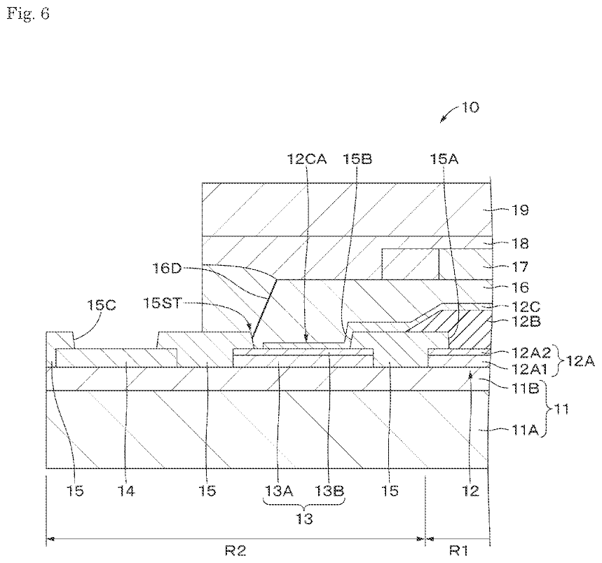

In the above-described embodiment, an example in which the height of the step 15ST is substantially equal to the height of the side surface of the second electrode 12C has been described. However, the height of the step 15ST may be higher than the height of the side surface of the second electrode 12C as shown in FIG. 6. In this case, a crack 16D generated during or after the formation of the protective layer 16 extends from the step 12ST in a direction inclined toward the element formation region R1 with respect to the thickness direction of the protective layer 16. Thus, the crack 16D is not electrically connected to the outside of the display device 10 through the side surface of the protective layer 16. Therefore, it is possible to prevent moisture or the like from entering the display device 10 from the outside. Therefore, deterioration in reliability of the display device 10 can be suppressed. Here, the height of the step 15ST and the height of the side surface of the second electrode 12C mean the height from the first surface of the contact portion 13 as a reference.

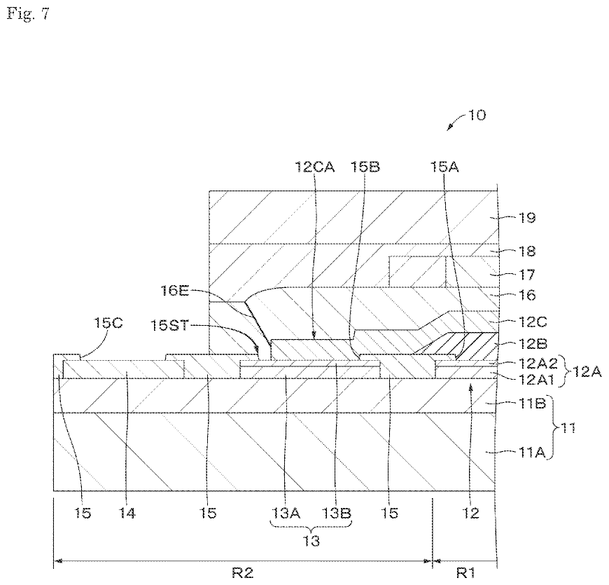

As shown in FIG. 7, the height of the side surface of the second electrode 12C may be higher than the height of the step 15ST. In this case, a crack 16E generated during or after the protective layer 16 is formed extends from the side surface (end surface) of the second electrode 12C in a direction inclined toward the outer circumference side of the display device 10 with respect to the thickness direction of the protective layer 16. In the display device 10 according to Modification Example 2, the peripheral edge of the second electrode 12C is provided closer to the element formation region R1 than the step 15ST. Thus, the distance between the peripheral edge of the second electrode 12C and the peripheral edge of the protective layer 16 is increased as compared to the conventional display device 110 (see FIG. 4). Therefore, even if the crack 16E extends in a direction inclined toward the outer circumference side as described above, the crack 16E is prevented from reaching the side surface of the protective layer 16.

Further, when the peripheral edge of the second electrode 12C is in the vicinity of the step 15ST on the side closer to the element formation region R1 than the step 15ST, the step substantially formed by the side surface of the second electrode 12C is lowered by the height of 15ST (that is, by the thickness of the insulating layer 15 on the contact portion 13). Therefore, the step substantially formed in the peripheral region R2 by the second electrode 12C is lower than that when the second electrode 12C is provided over the step 15ST (see FIG. 4).

Therefore, even in the case of the configuration shown in FIG. 7, it is possible to suppress deterioration in the reliability of the display device 10.

### Modification Example 3

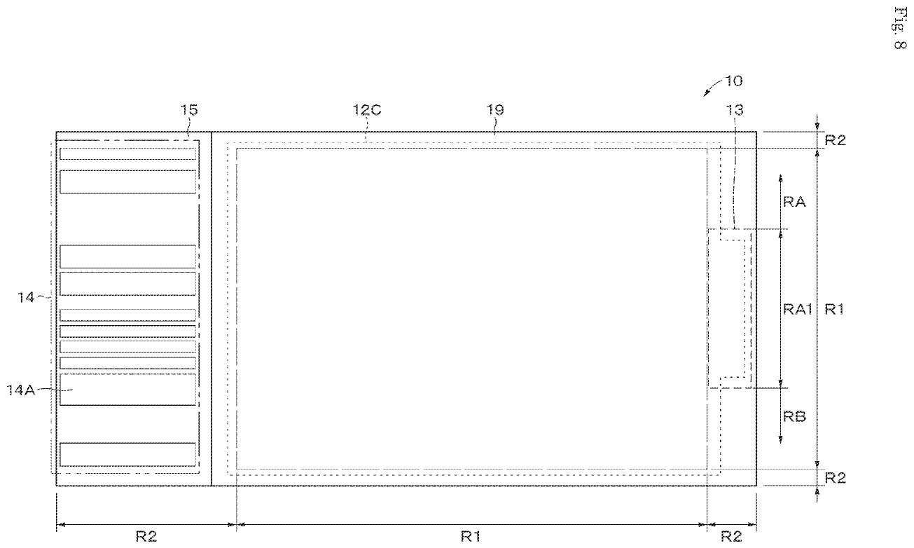

In the above-described embodiment, an example in which the contact portion 13 has a closed loop shape surrounding the peripheral edge of the element formation region R1 has been described. However, as shown in FIG. 8, the contact portion 13 may be provided so as to face a portion (first portion) of the outer circumference of the element formation region R1. Specifically, the peripheral region R2 may have a first peripheral region RA which is provided so as to face a portion (first portion) of the outer circumference of the element formation region R1, and in which the contact portion 13 is formed, and a second peripheral region RB which is provided so as to face another portion (second portion) of the outer circumference of the element formation region R1 and in which the contact portion 13 is not formed. In the display device 10 having such a configuration, the area of the element formation region R1 can be made larger than that in the display device 10 according to the above-described embodiment. That is, it is possible to increase the area of the effective display region. The second peripheral region RB is preferably provided to face the long side or short side of the rectangular element formation region R1.

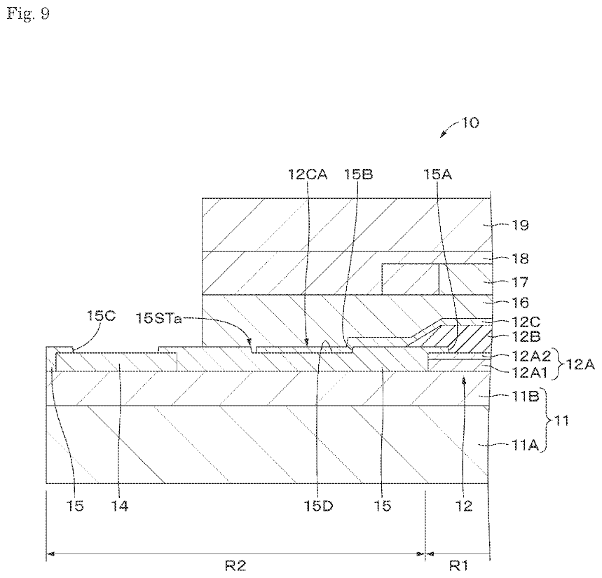

As shown in FIG. 9, a step 15STa may be provided in the second peripheral region RB. The step 15STa extends in the circumferential direction of the peripheral region R2. Like the step 15ST, the step 15STa rises in the direction from the inner side of the display device 10 to the outer circumference side. The peripheral edge of the second electrode 12C is preferably provided in the vicinity of the step 15STa on the side closer to the element formation region R1 than the step 15STa. In this way, it is possible to suppress the occurrence of cracks 16A in the protective layer 16 in both the first peripheral region RA and the second peripheral region RB.

As shown in FIG. 9, the insulating layer 15 may have, on its first surface, a recess 15D provided so as to face another portion (second portion) of the outer circumference of the element formation region R1, and a step 15STa may be formed by the side wall on the outer circumference side of the recess 15D. The recess 15D may be connected to a second opening 15B formed on the first surface of contact portion 13. The step 15ST and the step 15STa may be flush with each other. The first surface of the contact portion 13 and the bottom surface of the recess 15D may be at the same height. The step 15ST and the step 15STa may be at the same height.

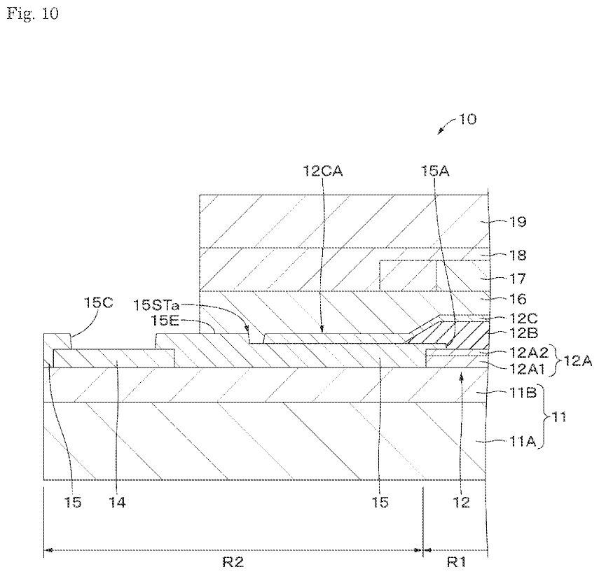

As shown in FIG. 10, in the second peripheral region RB, the insulating layer 15 may have a protrusion 15E on the side closer to the outer circumference side of the display device 10 than the peripheral edge of the second electrode 12C, and the step 15STa may be formed by the protrusion 15E.

The positional relationship between the peripheral edge of the second electrode 12C and the step 15ST in the first peripheral region RA and the positional relationship between the peripheral edge of the second electrode 12C and the step 15STa in the second peripheral region RB may be the same as the positional relationship between the peripheral edge of the second electrode 12C and the step 15ST in Modification Example 1 described above.

The relationship between the side surface of the second electrode 12C and the height of the step 15ST in the first peripheral region RA and the relationship between the side surface of the second electrode 12C and the height of the step 15STa in the second peripheral region RB may be the same as the relationship between the side surface of the second electrode 12C and the height of the step 15ST in Modification Example 2 described above.

### Modification Example 4

In the above-described embodiment, an example in which the display device 10 includes the contact portion 13 in the peripheral region R2 has been described, but the contact portion 13 may not be provided in the peripheral region R2. In this case, the configuration of the step 15ST in the peripheral region R2 may be the same as the configuration of the step 15STa in Modification Example 3 described above.

### Modification Example 5

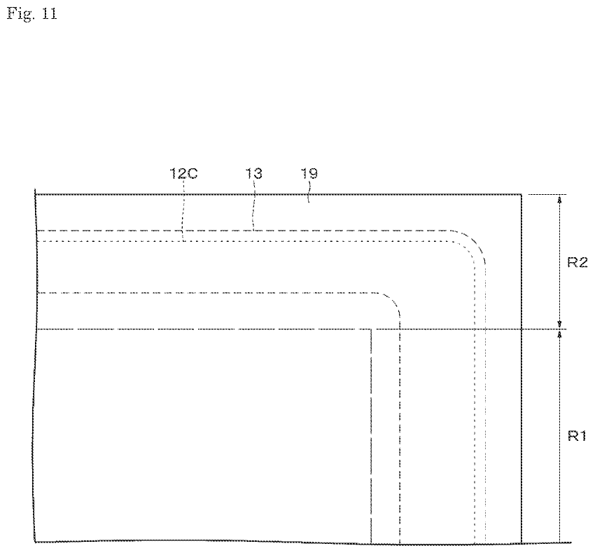

In the above-described embodiment, an example in which the corners of the contact portion 13 are formed by two orthogonal straight lines (see FIG. 3) has been described, but the corners of the contact portion 13 may be curved as shown in FIG. 11. That is, the inner circumference and the outer circumference of the contact portion 13 may be curved. Specifically, the corners of the inner circumference of the contact portion 13 may be curved in a concave shape, and the corners of the outer circumference of the contact portion 13 may be curved in a convex shape.

The corners of the second electrode 12C may be curved similarly to the contact portion 13 to form a curved shape. That is, the outer circumference of the second electrode 12C may be curved in a convex shape.

As shown in FIG. 3, if the corners of the contact portion 13 are formed by two orthogonal straight lines, film stress concentrates on the corners and cracks are likely to occur. On the other hand, if the corners of the contact portion 13 are curved as described above, it is possible to suppress the film stress from concentrating on the corners.

### 5 APPLICATION EXAMPLE

(Electronic Apparatus)

The display device 10 according to the above-mentioned embodiment and modification examples may be provided in various electronic apparatuses. In particular, it is preferable provided in an apparatus such as an electronic viewfinder or a head-mounted display of a video camera or a single-lens reflex camera, which requires a high resolution and is used in a magnified manner near the eyes.

### Specific Example 1

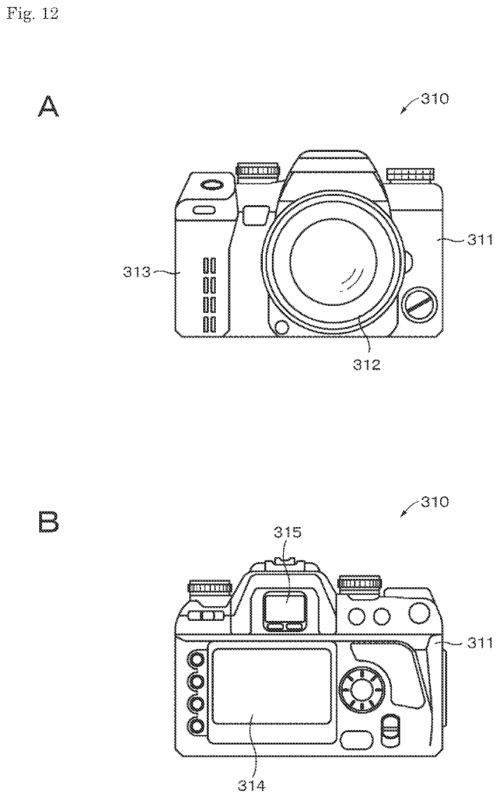

FIG. 12A is a front view showing an example of the appearance of a digital still camera 310. FIG. 12B is a rear view showing an example of the appearance of the digital still camera 310. This digital still camera 310 is an interchangeable single-lens reflex-type camera, and has an interchangeable photographing lens unit (interchangeable lens) 312 in approximately the center of the front surface of a camera main body (camera body) 311, and has a grip portion 313 for a photographer to hold on the left side of the front surface.

A monitor 314 is provided at a position shifted to the left from the center of the rear surface of the camera body 311. An electronic viewfinder (eyepiece window) 315 is provided above the monitor 314. By looking through the electronic viewfinder 315, the photographer can view the optical image of a subject guided from the photographing lens unit 312 and determine the composition. As the electronic viewfinder 315, any one of the display devices 10 according to the above-described embodiment and modification examples can be used.

### Specific Example 2

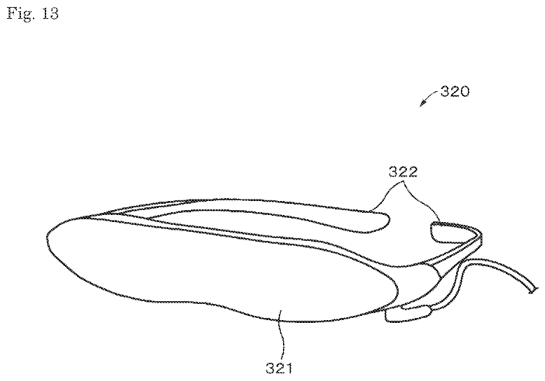

FIG. 13 is a perspective view showing an example of the appearance of a head-mounted display 320. The head-mounted display 320 has, for example, ear hooks 322 on both sides of an eyeglass-shaped display 321 to be worn on the user's head. As the display unit 321, any one of the display devices 10 according to the above-described embodiment and modification examples can be used.

### Specific Example 3

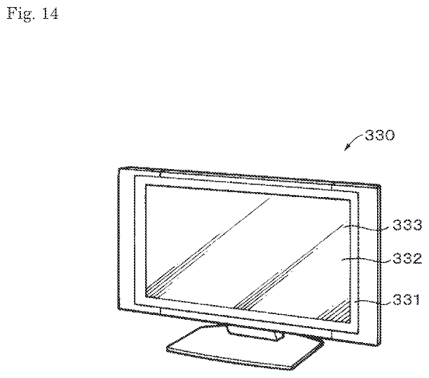

FIG. 14 is a perspective view showing an example of the appearance of a television device 330. This television device 330 has, for example, an image display screen portion 331 including a front panel 332 and a filter glass 333. This image display screen portion 331 is configured of any one of the display devices 10 according to the above-described embodiment and modification examples.

(Lighting Device)

Although an example in which the present disclosure is applied to a display device has been described in the above-described embodiment, the present disclosure is not limited to this, and the present disclosure may be applied to a lighting device. A lighting device is an example of a light-emitting device.

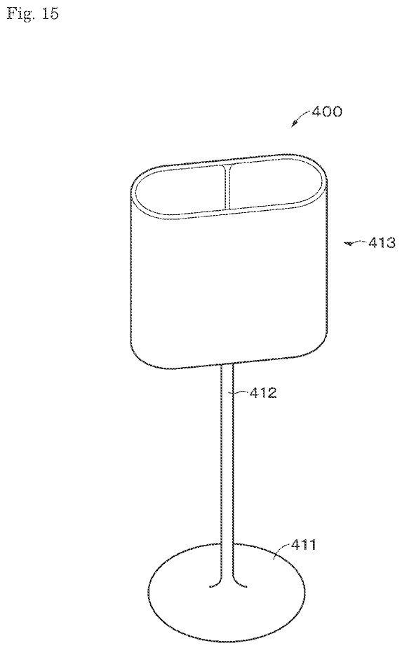

FIG. 15 is a perspective view showing an example of the appearance of a stand-type lighting device 400. This lighting device 400 has a lighting unit 413 attached to a post 412 provided on a base 411. As the lighting unit 413, the display device 10 according to any one of the above-described embodiment and modification examples, which is provided with a drive circuit for the lighting device instead of the drive circuit for the display device is used. Moreover, the color filter 17 may be omitted, and the size of the light-emitting element 12 may be appropriately selected according to the optical characteristics of the lighting device 400 and the like. Furthermore, by using a film as the substrate 11A and the counter substrate 19 and having a flexible configuration, it is possible to form any shape such as a cylindrical shape or a curved shape shown in FIG. 15. Note that the number of light-emitting elements 12 may be singular. Also, a monochromatic filter may be provided instead of the color filter 17.

Here, a case where the lighting device is the stand-type lighting device 400 has been described, but the form of the lighting device is not limited to this. For example, the lighting device may be installed on the ceiling, wall, floor, or the like.

While an embodiment of the present disclosure and its modification examples have been described above in detail, the present disclosure is not limited to the embodiment and its modification examples, and various modifications based on the technical idea of the present disclosure can be made.

For example, the configurations, methods, processes, shapes, materials, numerical values, and the like exemplified in the embodiment and its modification examples are only examples, and as necessary, different configurations, methods, processes, shapes, materials, numerical values, and the like may be used.

The configurations, methods, processes, shapes, materials, numerical values, and the like of the embodiment and its modification examples can be combined with each other as long as they do not deviate from the gist of the present disclosure.

Unless otherwise specified, the materials exemplified in the embodiment and its modification examples may be used alone or two or more thereof may be used in combination.

In addition, the present disclosure can also adopt the following configurations.

(1) A display device including:
a plurality of light-emitting elements;
a contact portion provided around a region in which the plurality of light-emitting elements are formed;
an insulating layer having a step on the contact portion; and
a protective layer covering the light-emitting elements, the contact portion, and the insulating layer, wherein
each of the light-emitting elements includes:
a first electrode;
a second electrode having a peripheral portion connected to the contact portion; and
a light-emitting layer disposed between the first electrode and the second electrode, wherein
the step rises in a direction from an inner side of the display device toward an outer circumference side, and
a peripheral edge of the second electrode is provided closer to the region than the step.
(2) The display device according to (1), wherein
the insulating layer has an opening that exposes the contact portion, and
the step is formed by an inner wall of the opening.
(3) The display device according to (1) or (2), wherein
the peripheral edge of the second electrode is provided in the vicinity of the step.
(4) The display device according to any one of (1) to (3), wherein
a distance between the step and the peripheral edge of the second electrode is 10 μm or less.
(5) The display device according to any one of (1) to (3), wherein
a distance between the step and the peripheral edge of the second electrode exceeds 10 μm.
(6) The display device according to any one of (1) to (3), wherein
a distance between a peripheral edge of the protective layer and the peripheral edge of the second electrode is 10 μm or less.
(7) The display device according to any one of (1) to (6), wherein
a height of the step is approximately equal to a height of a side surface of the second electrode.
(8) The display device according to any one of (1) to (6), wherein
a height of the step is higher than a height of a side surface of the second electrode.
(9) The display device according to any one of (1) to (6), wherein
a height of a side surface of the second electrode is higher than a height of the step.
(10) The display device according to any one of (1) to (9), wherein the contact portion has a closed loop shape surrounding the region.
(11) The display device according to any one of (1) to (10), wherein
the contact portion is provided so as to face a first portion of an outer circumference of the region.
(12) The display device according to (11), wherein
the insulating layer has another step provided so as to face a second portion of the outer circumference of the region, and
the other step rises from the inner side of the display device toward the outer circumference side.
(13) The display device according to (11), wherein
the insulating layer has a recess provided so as to face another portion of the outer circumference of the region, and
the recess forms a step that rises from the inner side of the display device toward the outer circumference side.
(14) The display device according to any one of (1) to (13), wherein
corners of the contact portions are curved.
(15) The display device according to any one of (1) to (14), wherein
the protective layer is made of an inorganic material.
(16) A light-emitting device including:
a plurality of light-emitting elements;
a contact portion provided around a region in which the plurality of light-emitting elements are formed;
an insulating layer having a step on the contact portion; and
a protective layer covering the light-emitting elements, the contact portion, and the insulating layer, wherein
each of the light-emitting elements includes:
a first electrode;
a second electrode having a peripheral portion connected to the contact portion; and
a light-emitting layer disposed between the first electrode and the second electrode, wherein
the step rises in a direction from an inner side of the light-emitting device toward an outer circumference side, and
a peripheral edge of the second electrode is provided closer to the region than the step.
(17) A display device including:
a plurality of light-emitting elements;
an insulating layer having a step around a region in which the plurality of light-emitting elements are formed; and
a protective layer covering the light-emitting elements and the insulating layer, wherein
each of the light-emitting elements includes:
a first electrode;
a second electrode having a peripheral edge extending to a periphery of the region; and
a light-emitting layer disposed between the first electrode and the second electrode, wherein
the step rises in a direction from an inner side of the display device toward an outer circumference side, and
a peripheral edge of the second electrode is provided closer to the region than the step.
(18) A light-emitting device including:
a plurality of light-emitting elements;
an insulating layer having a step around a region in which the plurality of light-emitting elements are formed; and
a protective layer covering the light-emitting elements and the insulating layer, wherein
each of the light-emitting elements includes:
a first electrode;
a second electrode having a peripheral edge extending to a periphery of the region; and
a light-emitting layer disposed between the first electrode and the second electrode, wherein
the step rises in a direction from an inner side of the light-emitting device toward an outer circumference side, and
a peripheral edge of the second electrode is provided closer to the region than the step.
(19) An electronic apparatus including the display device according to any one of (1) to (15) and (17).
(20) An electronic apparatus including the light-emitting device according to (16) or (18).

### REFERENCE SIGNS LIST

10 Display device (light-emitting device)
11 Drive substrate
11A Substrate
11B Insulating layer
12A First electrode
12A1 Metal layer
12A2 Metal oxide layer
12B Organic layer
12C Second electrode
12CA Peripheral portion
12ST Steps
13 Contact portion
13A Metal layer
13B Metal oxide layer
13A Metal layer
13B Metal oxide layer
14 Pad portion
15 Insulating layer
15A First opening
15B Second opening
15C Third opening
15D Recess
15E Protrusion
15ST, 15Sta Step
16 Protective layer
16A, 16B, 16C, 16D, 16E Crack
17 Color filter
18 Filling resin layer
19 Counter substrate
310 Digital still camera (electronic apparatus)
320 Head-mounted display (electronic apparatus)
330 Television device (electronic apparatus)
400 Lighting device (light-emitting device)
R1 Element formation region
R2 Peripheral region
RA First peripheral region
RB Second peripheral region

1. A display device comprising:
a plurality of light-emitting elements;
a contact portion provided around a region in which the plurality of light-emitting elements are formed;
an insulating layer having a step on the contact portion; and
a protective layer covering the light-emitting elements, the contact portion, and
the insulating layer, wherein
each of the light-emitting elements includes:
a first electrode;
a second electrode having a peripheral portion connected to the contact portion; and
a light-emitting layer disposed between the first electrode and the second electrode, wherein
the step rises in a direction from an inner side of the display device toward an outer circumference side, and
a peripheral edge of the second electrode is provided closer to the region than the step.

2. The display device according to claim 1, wherein
the insulating layer has an opening that exposes the contact portion, and
the step is formed by an inner wall of the opening.

3. The display device according to claim 1, wherein
the peripheral edge of the second electrode is provided in the vicinity of the step.

4. The display device according to claim 1, wherein
a distance between the step and the peripheral edge of the second electrode is 10 μm or less.

5. The display device according to claim 1, wherein
a distance between the step and the peripheral edge of the second electrode exceeds 10 μm.

6. The display device according to claim 1, wherein
a distance between a peripheral edge of the protective layer and the peripheral edge of the second electrode is 10 μm or less.

7. The display device according to claim 1, wherein
a height of the step is approximately equal to a height of a side surface of the second electrode.

8. The display device according to claim 1, wherein
a height of the step is higher than a height of a side surface of the second electrode.

9. The display device according to claim 1, wherein
a height of a side surface of the second electrode is higher than a height of the step.

10. The display device according to claim 1, wherein
the contact portion has a closed loop shape surrounding the region.

11. The display device according to claim 1, wherein
the contact portion is provided so as to face a first portion of an outer circumference of the region.

12. The display device according to claim 11, wherein
the insulating layer has another step provided so as to face a second portion of the outer circumference of the region, and
the other step rises from the inner side of the display device toward the outer circumference side.

13. The display device according to claim 11, wherein
the insulating layer has a recess provided so as to face another portion of the outer circumference of the region, and
the recess forms a step that rises from the inner side of the display device toward the outer circumference side.

14. The display device according to claim 1, wherein
corners of the contact portions are curved.

15. The display device according to claim 1, wherein
the protective layer is made of an inorganic material.

16. A light-emitting device comprising:
a plurality of light-emitting elements;
a contact portion provided around a region in which the plurality of light-emitting elements are formed;
an insulating layer having a step on the contact portion; and
a protective layer covering the light-emitting elements, the contact portion, and
the insulating layer, wherein
each of the light-emitting elements includes:
a first electrode;
a second electrode having a peripheral portion connected to the contact portion; and
a light-emitting layer disposed between the first electrode and the second electrode, wherein
the step rises in a direction from an inner side of the light-emitting device toward an outer circumference side, and
a peripheral edge of the second electrode is provided closer to the region than the step.

17. A display device comprising:
a plurality of light-emitting elements;
an insulating layer having a step around a region in which the plurality of light-emitting elements are formed; and
a protective layer covering the light-emitting elements and the insulating layer, wherein
each of the light-emitting elements includes:
a first electrode;
a second electrode having a peripheral edge extending to a periphery of the region; and
a light-emitting layer disposed between the first electrode and the second electrode, wherein
the step rises in a direction from an inner side of the display device toward an outer circumference side, and
a peripheral edge of the second electrode is provided closer to the region than the step.

18. A light-emitting device comprising:
a plurality of light-emitting elements;
an insulating layer having a step around a region in which the plurality of light-emitting elements are formed; and
a protective layer covering the light-emitting elements and the insulating layer, wherein
each of the light-emitting elements includes:
a first electrode;
a second electrode having a peripheral edge extending to a periphery of the region; and
a light-emitting layer disposed between the first electrode and the second electrode, wherein
the step rises in a direction from an inner side of the light-emitting device toward an outer circumference side, and
a peripheral edge of the second electrode is provided closer to the region than the step.

19. An electronic apparatus comprising the display device according to claim 1.
